(19) United States
(12) Patent Application Publication
(10) Pub. No.: US 2015/0017817 A1
(43) Pub. Date: Jan. 15, 2015

(54) LASER PROCESSING APPARATUS AND LASER PROCESSING METHOD

(71) Applicants: AISIN SEIKI KABUSHIKI KAISHA, Kariya-shi (JP); TOYOTA JIDOSHA KABUSHIKI KAISHA, Toyota-shi (JP)

(72) Inventors: Hiroyoshi HIEJIMA, Kariya-shi (JP); Michiharu OTA, Milpitas, CA (US); Yuta FURUMURA, Nagakute-shi (JP)

(73) Assignees: TOYOTA JIDOSHA KABUSHIKI KAISHA, Toyota-shi (JP); AISIN SEIKI KABUSHIKI KAISHA, Kariya-shi (JP)

(21) Appl. No.: 14/329,330

(22) Filed: Jul. 11, 2014

(30) Foreign Application Priority Data
Jul. 12, 2013 (JP) 2013-145987

(51) Int. Cl. H01L 21/263; H01L 21/268; H01S 3/11

(52) U.S. Cl. CPC H01L 21/2636; H01S 3/11; H01L 21/268
USPC 438/795; 372/30

(57) ABSTRACT

A laser processing apparatus includes a laser beam generating device that generates a first pulse laser beam for temporarily increasing a light absorptance in a predetermined region of a processing object, and a second pulse laser beam to be absorbed in the predetermined region in which the light absorptance has temporarily increased, and a support portion that is provided on a downstream of the first pulse laser beam and the second laser beam generated by the laser beam generating device and has a placement surface for placing the processing object. The laser beam generating device emits the second pulse laser beam with a delay with respect to the first pulse laser beam by a delay time within a predetermined period of time before the light absorptance that has temporarily increased in the predetermined region returns to an original value.

### INCORPORATION BY REFERENCE

The disclosure of Japanese Patent Application No. 2013-145987 filed on Jul. 12, 2013 including the specification, drawings and abstract is incorporated herein by reference in its entirety.

### BACKGROUND OF THE INVENTION

1. Field of the Invention

The invention relates to a laser processing apparatus and a laser processing method for processing a processing object by irradiation with a laser beam.

2. Description of Related Art

Laser annealing of a thin semiconductor film by irradiation of the thin semiconductor film with a high-intensity laser beam of a fundamental wave with a repetition frequency equal to or higher than 10 MHz and a pulse width of a picosecond or femtosecond order has been suggested (see Japanese Patent Application Publication No. 2006-148086 (JP 2006-148086 A) and Japanese Patent Application Publication No. 2006-173587 (JP 2006-173587 A). Such laser beam has a light intensity necessary to cause multi-photon absorption, and laser annealing is performed through absorption of the laser beam by the multi-photon absorption in the thin semiconductor film.

Further, Japanese Patent Application Publication No. 2006-156784 (JP 2006-156784 A) suggests performing laser annealing by irradiating an irradiated region with the first pulse laser beam and then irradiating the irradiated region with the second pulse laser beam within a period (within a period equal to or shorter than 1000 ns) in which the thermal effect produced by the first pulse laser beam that has been incident immediately therebefore still remains in the irradiated region. A width of 100 ns to 200 ns can be considered for the pulse width of the first pulse laser beam and second pulse laser beam. This is because where the pulse width is too short, the peak intensity becomes too large and the thermal effect time is too short, and where the pulse width is too long, the peak intensity decreases. Further, a wavelength of 400 nm to 650 nm can be considered for the wavelength of the first pulse laser beam and second pulse laser beam. This is because the absorption coefficient of amorphous silicon as a processing object is not too small, and where the wavelength becomes too long, it is not desirable in view of efficient heating of the processing object.

With the techniques disclosed in JP 2006-148086 A and JP 2006-173587 A, the conversion loss caused by a nonlinear optical element is eliminated by directly using the fundamental wave of the laser beam with a pulse width of a picosecond or femtosecond order, and a thin semiconductor film of a large surface area can be laser annealed by inducing the multi-photon absorption. In order to perform the multi-photon absorption efficiently, the peak power density of the laser beam should be increased. However, where the laser beam spot is decreased in size, the surface area of annealing performed by multi-photon absorption also decreases. Therefore, the processing time required for the annealing increases. Conversely, where the laser beam spot is increased in size, the peak power density of the laser beam decreases, the probability of multi-photon absorption decreases, and the efficiency of multi-photon absorption decreases.

Since the probability of multi-photon absorption is proportional to the second power of the peak power density of the laser beam, the probability of multi-photon absorption is strongly affected by changes in the laser beam absorption amount caused by the effect of differences in structure and composition of substrate and factors changing the excited level of impurities or the like. As a result, the degree of heating by multi-photon absorption and the temperature reached vary depending on the processing location. Further, the processing performed with a femtosecond laser beam is not limited to melting of the substrate surface and easily becomes the ablation processing that removes part of the substrate. Therefore, in the annealing using a femtosecond laser, it is difficult to control the processing state and select the processing conditions.

Further, in the laser annealing using multi-photon absorption, the annealing processing is performed by increasing the femtosecond laser output such as to generate as much heat as possible. In this case, where dirt or defects are present on the substrate surface, absorption edges appear that are caused thereby and unintentional ablation processing can be performed. Such ablation caused by the dirt or defects present on the substrate surface does not occur at all times, but once it occurs the ablation processing tends to continue. Therefore, for example, where the annealing is performed by scanning a laser beam in a certain direction on a substrate, linear processing is performed on the substrate following this scanning, which results in a damaged substrate surface.

Further, in recent years the increase in electric current of power semiconductors has raised the demand for annealing performed to a deeper locations inside a semiconductor substrate (for example, a depth equal to or greater than 1 μm from the substrate surface). The thermal diffusion length with a femtosecond laser beam is less than that with a nanosecond laser beam, and heat transfer is more difficult with the femtosecond beam. Therefore, in laser annealing using multi-photon absorption using a femtosecond laser beam, even if the multi-photon absorption occurs in a deep region of the substrate at a distance from the substrate surface, the annealing is performed in such deep region, but the annealing reaching the substrate surface is unlikely to occur. Meanwhile, even when the multi-photon absorption and annealing proceed on the substrate surface, since the thermal diffusion length attained with the femtosecond laser beam is small, as mentioned hereinabove, the diffusion (transfer) of heat from the annealed surface portion to the inside portions is reduced. Therefore, the annealing practically does not occur inside the substrate. Thus, with the laser annealing based on multi-photon absorption using a femtosecond laser beam, even when the substrate surface is annealed, the annealing reaching deep regions in the substrate is unlikely to occur.

Further, with the technique disclosed in JP 2006-156784 A, when amorphous silicon is annealed using, as the first pulse laser beam and second pulse laser beam, a nanosecond laser beam with a wavelength of 400 nm to 650 nm and a pulse width of a nanosecond order, the annealing can be performed only in a shallow region close to the substrate surface. This is because the light with a wavelength of 400 nm to 650 nm is mostly absorbed close to the amorphous silicon surface and, therefore, it is highly probable that the quantity of light sufficient for annealing will not reach the deep regions. Further, where the amorphous silicon is crystallized by the annealing, the light absorptance further increases. Therefore, the first pulse laser beam and second pulse laser beam are almost entirely absorbed in a shallow region of the substrate and the quantity of light sufficient for annealing is unlikely to reach the deep regions of the substrate. Further, where the quantity of light sufficient for annealing reaching the deep regions of the substrate is to be transferred with consideration for absorption in the amorphous silicon, the intensity of laser beam should be increased. In this case, the substrate surface may be thermally damaged by heating with the high-intensity laser beam.

In the explanation above, amorphous silicon is considered by way of example as a material to be annealed, but in laser annealing using a nanosecond laser beam, the annealing reaching deep portions from the substrate is difficult to perform. From the standpoint of performing laser annealing, the wavelength of the laser beam to be used should be selected such as to increase the absorptance in the material to be processed. In this case, for the same reasons as descried hereinabove, the quantity of light sufficient for annealing reaching a deep region of the substrate is unlikely to be transferred.

### SUMMARY OF THE INVENTION

The invention provides a laser processing apparatus and a laser processing method that can extend the processing to a deeper region of the substrate from the substrate surface and can shorten the time of the processing while reducing the damage of the substrate surface by the laser beam for the processing.

An first aspect of the invention relates to a laser processing apparatus including: a laser beam generating device that generates a first pulse laser beam for temporarily increasing a light absorptance in a predetermined region of a processing object, and a second pulse laser beam to be absorbed in the predetermined region in which the light absorptance has temporarily increased, and a support portion that is provided on a downstream of the first pulse laser beam and the second laser beam generated by the laser beam generating device and has a placement surface for placing the processing object. The laser beam generating device emits the second pulse laser beam with a delay with respect to the first pulse laser beam by a delay time within a predetermined period of time before the light absorptance that has temporarily increased in the predetermined region returns to an original value.

A second aspect of the invention relates to a laser processing method including: irradiating a predetermined region of a processing object with a first pulse laser beam for temporarily increasing a light absorptance of the predetermined region; and irradiating the processing object with a second pulse laser beam to be absorbed by the predetermined region such that the predetermined region in which the light absorptance has temporarily increased and an irradiation region of the second pulse laser beam at least partially overlap, before the light absorptance in the region in which the light absorptance has temporarily increased returns to an original value.

In accordance with the aspects of the invention, the processing reaching the deeper regions of the substrate from the substrate surface can be performed and the processing time can be shortened while reducing the damage of the substrate surface by the laser beams used for the processing.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a schematic diagram of a laser annealing device of an embodiment of the invention;

FIG. 2 shows the configuration of the light source emitting laser beams in the embodiment of the invention;

FIGS. 3A to 3D are schematic diagrams for explaining the laser annealing according to the embodiment of the invention;

FIG. 4 shows sheet resistance values of the examples and comparative examples according to the embodiment of the invention; and

FIG. 5 shows the relationship between the power of a femtosecond laser beam and the power of a nanosecond laser beam at which the annealing according to the embodiment of the invention can be realized.

### DETAILED DESCRIPTION OF EMBODIMENTS

Embodiments of the invention will be explained hereinbelow with reference to the appended drawings, but the invention is not limited to those embodiments. In the figures explained hereinabove, components having same functions are denoted by like reference numerals and the redundant explanation thereof is herein omitted.

### First Embodiment

In the present embodiment, a first pulse laser beam and a second pulse laser beam are used, a starting point region serving as a starting point for forming a high-temperature portion is formed by the first pulse laser beam in the predetermined region (surface of a preprocessing object, for example, a semiconductor layer such as a silicon layer, or inside the processing object) of the processing object, and then the starting point region is heated with the second pulse laser beam to raise the temperature of a region (high-temperature portion) including the starting point region. Annealing such as crystallization and activation is an example of such heating treatment. The above heating treatment can be also used for local heating treatment other than the annealing.

More specifically, a region (can be also referred to hereinbelow as “light absorptance increase region”) with a light absorptance higher than that in other regions of the processing object is temporarily formed on the surface or inside the processing object by irradiation with the first pulse laser beam under the conditions of multi-photon absorption generation. Thus, a region (can be also referred to hereinbelow as “multi-photon absorption zone”) in which multi-photon absorption occurs is formed in the processing object by the first pulse laser beam. The position of the multi-photon absorption zone in the thickness direction can be controlled by regulating a laser optical system. Plasma (free electrons, holes) is generated by the multi-photon absorption, and the region in which the plasma has been generated becomes the light absorptance increase region. An ultrashort-pulse laser beam is preferred as the first pulse laser beam. It is also preferred that the irradiation with the first pulse laser beam be performed under the conditions such that the multi-photon absorption is generated in the processing object, but no ablation occurs.

Then, while the light absorptance increase region is being formed, the light absorptance increase region is irradiated with the second pulse laser beam with a power higher than that of the first pulse laser beam, and the second pulse laser beam is absorbed in the light absorptance increase region. In the light absorptance increase region, the light absorptance temporarily increases by comparison with regions of the processing object other than the light absorptance increase region. As result, the light absorptance increase region assumes a state in which light absorption is facilitated by comparison with that in the processing object in the usual state. In the present embodiment, the second pulse laser beam is caused to be incident upon the light absorptance increase region before the light absorptance of the light absorptance increase region, in which the light absorptance has temporarily increased, returns to an original value. Thus, the irradiation with the second pulse laser beam is performed for the retention time of plasma generated after the irradiation with the first pulse laser beam. Therefore, even in the case in which a pulse laser beam is used under the conditions (wavelength, intensity, and repetition frequency) such that the desired heating (annealing or the like) cannot be realized at a specific position inside the processing object in the usual processing, light sufficient for performing the desired heating of the processing object at the specific position can be caused to be absorbed by forming the light absorptance increase region such that the specific position is included. As a result, the desired heating treatment (annealing or the like) can be performed in the light absorptance increase region.

A laser beam (for example, a nanosecond laser beam and a pulse laser beam with a pulse width larger than that of the nanosecond laser beam), which is linearly absorbed in the processing object and used in the usual laser annealing, may be used as the second pulse laser beam. It is preferred that a laser beam with a pulse width longer than the time (thermal diffusion time of the processing object), in which laser beam is absorbed in the light absorptance increase region and thermal conduction (transfer of heat to surroundings by oscillations of atoms in the light absorptance increase region) occurs from the light absorptance increase region, be used as the second pulse laser beam. By setting such a pulse width, it is possible to perform effectively the diffusion of heat by laser irradiation and expand the high-temperature portion formed by the irradiation with the second pulse laser beam to the second pulse laser beam irradiation side inside the processing object.

For example, when focusing on the annealing, where the light absorptance increase region is formed in a deep region of the processing object, the annealing should be performed from the light absorptance increase region to the surface. In order to realize such annealing, as mentioned hereinabove, the light absorptance increase region is irradiated with a laser beam and/or a plurality of laser beams with a large pulse width, thereby enabling the annealing that reaches the surface. In the present embodiment, a method for inducing larger thermal diffusion and light absorption on the laser beam incidence side of the processing object is used as a method for annealing from the deep region, in which the light absorptance increase region has been formed, to the surface. Thermal diffusion is represented by the following Eq. (1):

$$ρ C \frac{\partial T}{\partial t} = ∇ \cdot ( k ∇ T )$$

where ρ stands for the density of the processing object, C—the specific heat of the processing object, T—temperature, and k—thermal conductivity.

Where the light absorptance increase region that has become a high-temperature portion as a result of irradiation with the second pulse laser beam is further irradiated with the second pulse laser beam, the temperature of the region on the laser incidence side with respect to the light absorptance increase region is increased by thermal diffusion. Where the above-described operations are repeated, the annealing can reach the surface of the processing object (for example, silicon). Thus, the temperature of the region that is close to the light absorptance increase region and is on the surface side with respect to the light absorptance increase region is increased by thermal diffusion. As a result, the light absorptance in the region on the surface side increased. Thus, the absorption amount of the second pulse laser beam increases also in the region on the surface side and this region becomes a high-temperature portion. As a result of thermal diffusion from this high-temperature portion, the temperature and the light absorptance of the region that is close to the high-temperature portion and is on the surface side with respect to the high-temperature portion increases. Therefore, the absorption amount of the second pulse laser beam in this region increases and this region becomes a high-temperature portion. As a result of repeating those steps, the high-temperature portions are formed toward the substrate surface side from the light absorptance increase region as a starting point, and the annealing reaches the surface.

In the present embodiment, the irradiation with the second pulse laser beam may be performed such that the light absorptance increase region is included in the irradiation region of the second pulse laser beam or such that the irradiation region of the second pulse laser beam is included in the light absorptance increase region, provided that the formation of the high-temperature portions from the light absorptance increase region as a starting point can be realized by irradiation with the second pulse laser beam. Alternatively, the irradiation with the second pulse laser beam may be performed such that part of the irradiation region of the second pulse laser beam is included in the light absorptance increase region. That is, it is only necessary that the irradiation region (for example, focal point) of the second pulse laser beam at least partially overlaps the light absorptance increase region.

The “light absorptance increase region”, as referred to in the present specification, is a region which is temporarily formed by irradiation with the first pulse laser beam under predetermined conditions and in which the absorptance of the second pulse laser beam temporarily increases for a predetermined time after the irradiation with the first pulse laser beam under the predetermined conditions. Therefore, the light absorptance increase region returns to the original state once the predetermined time elapses.

Further, the “predetermined time” as referred to in the present specification is a period of time from the point of time at which the predetermined region (part of the surface or part of the inside) of the processing object has become the light absorptance increase region under the effect of the first pulse laser beam incident under the predetermined conditions till the return to the original state. In other words, the “predetermined time” is a duration of the light absorptance increase region. For example, the lifespan of plasma (electrons, holes) generated by a femtosecond laser beam is several hundreds of picoseconds. Therefore, the second pulse laser beam of sufficient power is caused to be incident within the lifespan period (within the predetermined time) after the light absorptance increase region has been generated.

Thus, in the present embodiment, the first pulse laser beam is used to form in the processing object (surface or inside of the processing object) the light absorptance increase region in which the light absorptance temporarily increases with respect to the predetermined laser beam and then returns to the original value once the predetermined time elapses. The processing object is then heated starting from the light absorptance increase region by using the second pulse laser beam which is longer in pulse width than the first pulse laser beam and generates the desired thermal diffusion. Thus, the second pulse laser beam is efficiently absorbed in the light absorptance increase region, the region including the light absorptance increase region is heated, and a region (high-temperature portion) with a temperature higher than other regions is formed. Thus, the irradiation with the first pulse laser beam does not serve to heat the target region, but has a function of forming a basis when heating with the second pulse laser beam, that is, a function of forming the light absorptance increase region.

In the present embodiment, laser beams having the above-mentioned functions are used as the first pulse laser beam and second pulse laser beam.

In the present embodiment, an ultrashort-pulse laser beam that is transparent or substantially transparent with respect to the processing object, and a femtosecond laser beam is more preferably used as the first pulse laser beam. When a femtosecond laser beam is used as the first pulse laser beam, the pulse width is preferably equal to or less than 30 ps, more preferably equal to or less than 20 ps, and still more preferably from 10 fs to 20 ps.

Where a femtosecond laser beam is used as the first pulse laser beam, the region (light absorptance increase region) in which the light absorptance with respect to the second pulse laser beam (for example, a nanosecond laser beam or a sub-nanosecond laser beam) is higher than in other regions is temporarily formed in part (surface or inside) of the processing object. In the present embodiment, any laser beam may be used as the first pulse laser beam, provided that it is an ultrashort pulse laser beam that can convert part of the processing object into the light absorptance increase region of the present embodiment, for example, a femtosecond laser beam such as mentioned hereinabove. The irradiation conditions for the first pulse laser beam are preferably such that multi-photon absorption occurs, but the laser focus point and the periphery thereof are not melted by heat. However, the irradiation conditions for the first pulse laser beam may also be conditions that do not take into consideration the melting of the laser focus point and/or the periphery thereof by heat. It is also preferred that the conditions be such that no ablation occurs in part of the substrate serving as the processing object (substrate surface on the incidence side, focus point portion, and the like).

Further, in the present embodiment, it is preferred that a short pulse laser beam with a pulse width larger than that of the first pulse laser beam be used as the second pulse laser beam, it is more preferred that a short pulse laser beam with a pulse width from 100 ps to 1 μm be used, and it is even more preferred that a short pulse laser beam with a pulse width from 100 ps to 20 ns be used. For example, a nanosecond laser beam, a sub-nanosecond laser beam, and a pulse laser beam having a pulse width longer than that of nanosecond order can be used as the second pulse laser beam. Where a nanosecond laser beam or a sub-nanosecond laser beam is used as the second pulse laser beam, a light absorptance increase region can be locally heated when the light absorptance increase region is formed inside (deep portion) of the processing object by using a femtosecond laser beam as the first pulse laser beam. In the present embodiment, any laser beam may be used as the second pulse laser beam, provided that it is a laser beam which has a wavelength band absorbable in the formed light absorptance increase region and which is transparent or substantially transparent with respect to regions of the processing object other than the light absorptance increase region, such as the aforementioned nanosecond laser beam and sub-nanosecond laser beam.

Further, in the present embodiment, it is not necessary that both the first pulse laser beam and the second pulse laser beam be transparent or substantially transparent with respect to the processing object. In the present embodiment, the light absorptance increase region is formed by irradiating part of the processing object (part of the inside or surface) with the first pulse laser beam, and the light absorptance increase region is heated by irradiating the light absorptance increase region with the second pulse laser beam. Therefore, whether or not the absorption occurs during the irradiation, or the degree of the absorption, is irrelevant, provided that the irradiation with the first pulse laser beam and second pulse laser beam is performed under conditions such that the desired results are obtained in the region to be irradiated. For example, when a region with a small laser annealing depth (i.e., shallow region) is laser annealed, the formation and heating of the light absorptance increase region can be effectively performed even when the processing object is semi-transparent. Further, the formation and heating of the light absorptance increase region can be effectively performed by adjusting the laser output even with respect to a (deep) region with a large laser annealing depth i.e., deep region) when the processing object is semi-transparent.

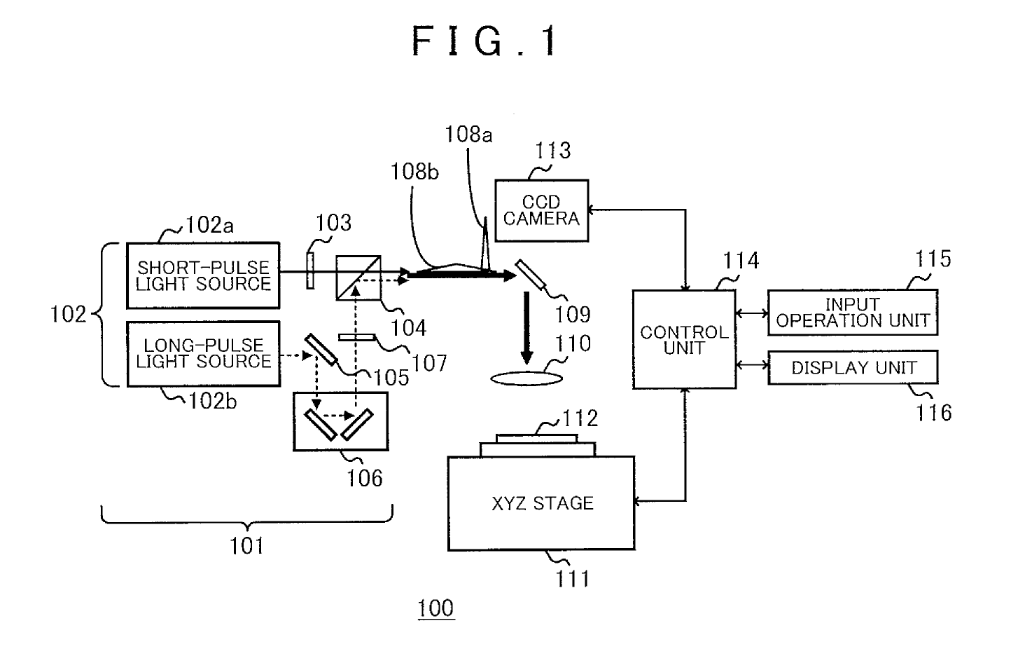

FIG. 1 is a schematic diagram of a laser annealing device 100 according to the present embodiment. The laser annealing device 100 is provided with a laser beam generating device 101 that individually emits a femtosecond laser beam as a first pulse laser beam and a nanosecond laser beam as a second pulse laser beam and emits the first pulse laser beam in spatial superposition with the second pulse laser beam delayed by a predetermined time with respect to the first pulse laser. The laser beam generating device 101 has a light source 102, a ½-wavelength plate 103, a polarization beam splitter (PBS) 104, a mirror 105, a delay circuit 106, and a ½-wavelength plate 107.

The light source 102 is capable of generating independently a femtosecond laser beam and a nanosecond laser beam and also of synchronously generating a femtosecond laser beam and a nanosecond laser beam. The light source 102 has a short-pulse light source 102a generating a femtosecond laser beam and a long-pulse light source 102b generating a nanosecond laser beam.

The ½-wavelength plate 103 is provided on the downstream side of the short-pulse light source 102a in the laser beam propagation direction, and the PBS 104 is provided on the downstream of the ½-wavelength plate 103. In the present embodiment, the ½-wavelength plate 103 is configured such that the femtosecond laser beam generated by the short-pulse light source 102a is incident as P polarized light on the PBS 104. Therefore, the femtosecond laser beam outputted from the short-pulse light source 102a becomes P polarized light in the ½-wavelength plate 103 and is transmitted as such by the PBS 104. In the present specification, the downstream in the propagation direction of the laser beam outputted form the light source 102 will be simply referred to as “downstream”, and the upstream in the propagation direction of the laser beam outputted form the light source 102 will be simply referred to as “upstream”.

The mirror 105, delay circuit 106, and ½-wavelength plate 107 are provided in the order of description on the downstream of the long-pulse light source 102b. The mirror 105, delay circuit 106, and ½-wavelength plate 107 are aligned such that the nanosecond laser beam generated by the long-pulse light source 102b and reflected by the mirror 105 is incident on the PBS 104 through the delay circuit 106 and the ½-wavelength plate 107. In the present embodiment, the ½-wavelength plate 107 is configured such that the nanosecond laser beam generated from the long-pulse light source 102b is incident as S polarized light upon the PBS 104. Therefore, the nanosecond laser beam incident from the upstream of the ½-wavelength plate 107 becomes the S polarized light in the ½-wavelength plate 107 and this light is reflected by the PBS 104 and emitted to the downstream side of the PBS 104.

In the present embodiment, the PBS 104 is provided on the downstream side of either of the short-pulse light source 102a and the long-pulse light source 102b. Thus, the femtosecond laser beam generated from the short-pulse light source 102a and the nanosecond laser beam generated from the long-pulse light source 102b are incident upon the PBS 104 from the same direction. Therefore, the PBS 104 can function as a mixing unit for the femtosecond laser beam generated from the short-pulse light source 102a and the nanosecond laser beam generated from the long-pulse light source 102b.

In the present embodiment, the delay circuit 106 is configured such that when the femtosecond laser beam and the nanosecond laser beam are generated synchronously (simultaneously) from the short-pulse light source 102a and the long-pulse light source 102b, a certain nanosecond laser beam that has been generated from the long-pulse light source 102b is incident upon the PBS 104 with a delay by a certain time with respect to the femtosecond laser beam that has been generated from the short-pulse light source 102a synchronously with the certain nanosecond laser beam. The certain time is a period (for example, a time interval within 3 ns) in which a light absorptance increase region, which is formed when the femtosecond laser beam falls as a first pulse laser beam on the processing object, is retained. Therefore, where the generation of the femtosecond laser beam from the short-pulse light source 102a is performed synchronously with the generation of the nanosecond laser beam from the long-pulse light source 102b, a certain femtosecond laser pulse 108a and a nanosecond laser pulse 108b generated synchronously with the femtosecond laser pulse 108a are emitted from the PBS 104 with a temporal shift by the aforementioned certain time. Thus, the nanosecond laser pulse 108b is emitted from the PBS 104 with a delay by the certain time with respect to the femtosecond laser pulse 108a.

A dichroic filter 109, a lens 110, and an XYZ stage 111 are provided in the order of description on the downstream side of the PBS 104. The dichroic filter 109 is configured to reflect both the femtosecond laser beam emitted from the short-pulse light source 102a and the nanosecond laser beam emitted from the long-pulse light source 102b and transmit the visible light. Therefore, the laser beam which is emitted from the PBS 104 and in which the femtosecond laser and nanosecond laser are mixed is reflected by the dichroic filter 109 and incident through the lens 110 upon a processing object 112 held at the XYZ stage 111.

An X axis and an Y axis of the XYZ stage 111 are in the in-plane direction of the placement surface of the XYZ stage 111 for placing the processing object 112, and a Z axis is in the direction perpendicular to the placement surface. The XYZ stage 111 is configured such that the processing object 112 placed on the placement surface can be moved, as desired, along the X axis, Y axis, and Z axis. Further, in the present embodiment, the focus point of the visible light converged by the lens 110 and the focus point of the femtosecond laser beam and nanosecond laser beam converged by the lens 110 coincide.

A charge coupled device (CCD) camera 113 is provided facing the placement surface of the XYZ stage 111. The CCD camera 113 has a visible light source that generates visible light. The CCD camera 113, dichroic filter 109, lens 110, and XYZ stage 111 are aligned such that visible light generated from the visible light source is incident through the dichroic filter 109 upon the processing object 112 held at the XYZ stage 111 and the visible light reflected by the processing object 112 is incident through the dichroic filter 109 upon an image capturing element of the CCD camera 113.

A control unit 114 configured to control the XYZ stage 111 and the CCD camera 113 is electrically connected to the XYZ stage 111 and the CCD camera 113. The control unit 114 includes a central processing unit (CPU) configured to execute various processing operations such as computation, control, and identification, a read only memory (ROM) configured to store various control programs executed by the CPU, a random access memory (RAM) configured to temporarily store input data of data during processing operations performed by the CPU, and a nonvolatile memory such as a flash memory and a static random access memory (SRAM). Further, an input operation unit 115 including a keyboard for inputting predetermined commands or data and various switches, and a display unit 116 (for example, a display) that displays the input state and/or set state of the XYZ stage 111 and images captured by the CCD camera 113 are connected to the control unit 114.

An example of a method for setting the focus point of a predetermined laser beam to a predetermined position inside a processing object is explained below. When the focus point in which light is converged by the lens 110 is set on the surface of the processing object 112, the control unit 114 controls the XYZ stage 111 and the CCD camera 113 such that image capture data are acquired by the CCD camera 113 while the XYZ stage 111 with the processing object 112 placed thereon is moved in the Z axis direction in a state of illumination with the visible light from the CCD camera 113. The control unit 114 acquires the position of the XYZ stage 111 at the time where the focus point of the visible light converged by the lens 110 matches the surface of the processing object 112 on the basis of the image capture data acquired by the CCD camera 113. The acquired position of the XYZ stage 111 is stored as a reference position in the RAM of the control unit 114. The control unit 114 holds, as a reference position, the position of the XYZ stage 111 in the Z-axis direction at which the focus point of the light converged by the lens 110 matches the surface of the processing object 112. When the lens 110 is provided in the same position and the thickness of the processing object 112 is the same, a common reference position can be used.

Where the focus point of a femtosecond laser beam or a nanosecond laser beam is set through the lens 110 at a predetermined position inside the processing object, the position of the XYZ stage 111 in the Z-axis direction is changed using the reference position. For example, when the focus point is to be set to a position of x from the surface of the processing object 112, the user inputs x μm, as focus point distance information relating to the distance from the surface of the processing object 112 to the focus point with the input operation unit 115 and also inputs the refractive index of the processing object 112. The control unit 114 moves the XYZ stage 111 on the basis of the reference position stored in the RAM and matches the surface of the processing object 112 with the focus point obtained through the lens 110. The control unit 114 then calculates the distance corresponding to the x μm, at the inputted refractive index on the basis of the focus point distance information and the refractive index of the processing object 112 inputted by the user, and moves the XYZ stage 111 downward (the direction away from the lens 110 along the Z axis) through a predetermined distance from the reference position on the basis of the calculation result so that the focus point position arrives at the x μm position by moving inward from the surface of the processing object 112. As a result, the focus points of the femtosecond laser beam and nanosecond laser beam converged by the lens 110 are set to a predetermined position inside the processing object 112.

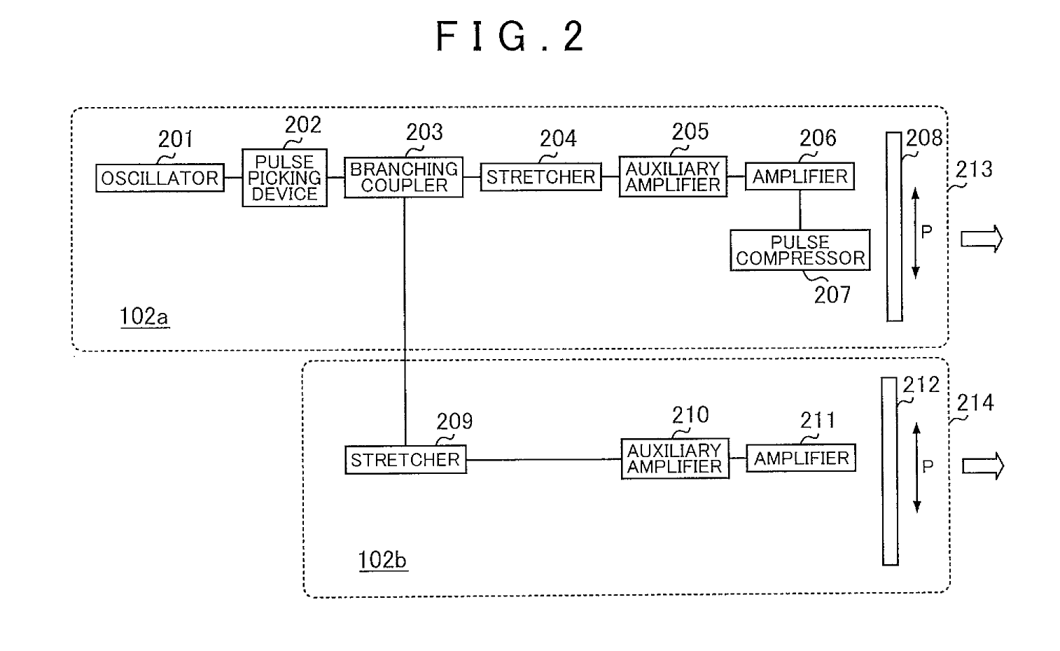

FIG. 2 shows the configuration of the light source 102 according to the present embodiment. In FIG. 2, the short-pulse light source 102a is provided with an oscillator 201, a pulse picking device 202, a branching coupler 203, a stretcher 204, an auxiliary amplifier 205, an amplifier 206, a pulse compressor 207, and a shutter 208. Meanwhile, the long-pulse light source 102b is provided with a stretcher 209, an auxiliary amplifier 210, an amplifier 211, and a shutter 212. The shutter 208 if configured not to be fractured even under the irradiation with the femtosecond laser beam emitted from the pulse compressor 207. Likewise, the shutter 212 if configured not to be fractured even under the irradiation with the nanosecond laser beam emitted from the amplifier 211.

In FIG. 2, the pulse picking device 202 is connected through an optical fiber to the downstream side of the oscillator 201 generating a 50 MHz, 100 fs laser beam. The pulse picking device 202 converts the 50 MHz, 100 fs laser beam inputted from the oscillator 201 into a 1 MHz, 100 fs laser beam which is emitted to the downstream side. The branching coupler 203, which is a 3 dB coupler, is connected through an optical fiber to the downstream side of the pulse picking device 202. The stretcher 204 is connected through an optical fiber to one output terminal of the branching coupler 203, and the stretcher 209 is connected through an optical fiber to the other terminal.

The stretcher 204 converts the 1 MHz, 100 fs laser beam emitted from one output terminal of the branching coupler 203 into a 1 MHz, 100 ps laser beam which is emitted to the downstream side. The auxiliary amplifier 205 is connected through an optical fiber to the downstream side of the stretcher 204, the amplifier 206 is connected through an optical fiber to the downstream side of the auxiliary amplifier 205, and the pulse compressor 207 is connected through an optical fiber to the downstream side of the amplifier 206. The pulse compressor 207 converts the laser beam emitted from the amplifier 206 into a 1 MHz, 800 fs laser beam, and the 1 MHz, 800 fs laser beam is emitted from an emission terminal 213 of the short-pulse light source 102a. Thus, the short-pulse light source 102a emits a 1 MHz, 800 fs femtosecond laser beam. In this case, since the shutter 208 movable in the arrow direction P is provided on the downstream of the pulse compressor 207, the short-pulse light source 102a switches on and off of the generation of the femtosecond laser beam by the opening/closing operation of the shutter 208.

Thus, in the present embodiment, by allowing a laser beam emitted from one output terminal of the branching coupler 203 to pass through the constituent elements included in the first path that optically connects the one output terminal of the branching coupler 203 with the emission terminal 213, it is possible to convert this laser beam into the femtosecond laser beam to be emitted.

Meanwhile, the stretcher 209 converts the 1 MHz, 100 fs laser beam emitted from the other output terminal of the branching coupler 203 into a 1 MHz, 10 ns laser beam which is emitted to the downstream side. The auxiliary amplifier 210 is connected through an optical fiber to the downstream side of the stretcher 209, and the amplifier 211 is connected through the optical fiber to the downstream side of the auxiliary amplifier 210. The 1 MHz, 10 ns laser beam emitted from the amplifier 211 is emitted from an emission terminal 214 of the long-pulse light source 102b. Therefore, the long-pulse light source 102b emits a 1 MHz, 10 ns nanosecond laser beam. In this case, since the shutter 212 movable in the arrow direction P is provided on the downstream side of the amplifier 211, the long-pulse light source 102b switches on and off of the generation of the nanosecond laser beam by the opening/closing operation of the shutter 212.

Thus, in the present embodiment, by allowing a laser beam emitted from the other output terminal of the branching coupler 203 to pass through the constituent elements included in the second path that optically connects the other output terminal of the branching coupler 203 with the emission terminal 214, it is possible to convert this laser beam into the nanosecond laser beam to be emitted.

In the present embodiment, the optical path length of the first path by which the laser beam emitted from the one output terminal of the branching coupler 203 reaches the emission terminal 213 of the short-pulse light source 102a and the optical path length of the second path by which the laser beam emitted from the other output terminal of the branching coupler 203 reaches the emission terminal 214 of the long-pulse light source 102b are set to be the same. Therefore, a single laser beam emitted from a single oscillator 201 can be branched and generated as mutually synchronized femtosecond laser beam and nanosecond laser beam. The adjustment of the optical path length may be performed by changing, as appropriate, for example, at least one of the length and refractive index of the optical fiber provided between the constituent elements.

Further, in the present embodiment, the short-pulse light source 102a and the long-pulse light source 102b are provided with the shutters 208, 212, respectively, and by combined opening/closing of the shutters 208, 212, it is possible to cause the light source 102 to emit a femtosecond laser beam alone and a nanosecond laser beam alone and also to emit simultaneously a femtosecond laser beam and a nanosecond laser beam synchronized with the femtosecond laser beam. The opening/closing control of the shutters 208, 212 may be performed by the control unit 114.

Further, in the present embodiment, the auxiliary amplifiers 205, 210 may be imparted with the function of ON/OFF switching of the incident laser beam. In this case, since the auxiliary amplifiers 205, 210 each can block the light incident from the upstream side, the selection of the laser beam emitted from the light source 102 can be performed by ON/OFF controlling of the auxiliary amplifiers 205, 210. For example, where the auxiliary amplifiers 205, 210 are both in the ON state, mutually synchronized femtosecond laser beam and nanosecond laser beam are emitted from the light source 102, and where the auxiliary amplifier 205 is set to the ON state and the auxiliary amplifier 210 is set to the OFF state, the light source 102 emits only a femtosecond laser beam. Likewise, where the auxiliary amplifier 205 is set to the OFF state and the auxiliary amplifier 210 is set to the ON state, the light source 102 emits only a nanosecond laser beam.

Further, the branching coupler 203 may be configured as a branching coupler having a branching ratio variable function. In this case, where the mutually synchronized femtosecond laser beam and nanosecond laser beam are emitted, the branching ratio on the one emission terminal and the other emission terminal of the branching coupler 203 may be set to 50:50, where only the femtosecond laser beam is to be emitted, the branching ratio may be set to 100:0, and where only the nanosecond laser beam is to be emitted, the branching ratio may be set to 0:100.

With such a configuration, the laser beam generating device provided with the short-pulse light source 102a, long-pulse light source 102b, ½-wavelength plate 103, PBS 104, mirror 105, delay circuit 106, and ½-wavelength plate 107 can generate the first and second pulse laser beams individually and can also generate the first and second pulse laser beams that are temporally and spatially superimposed.

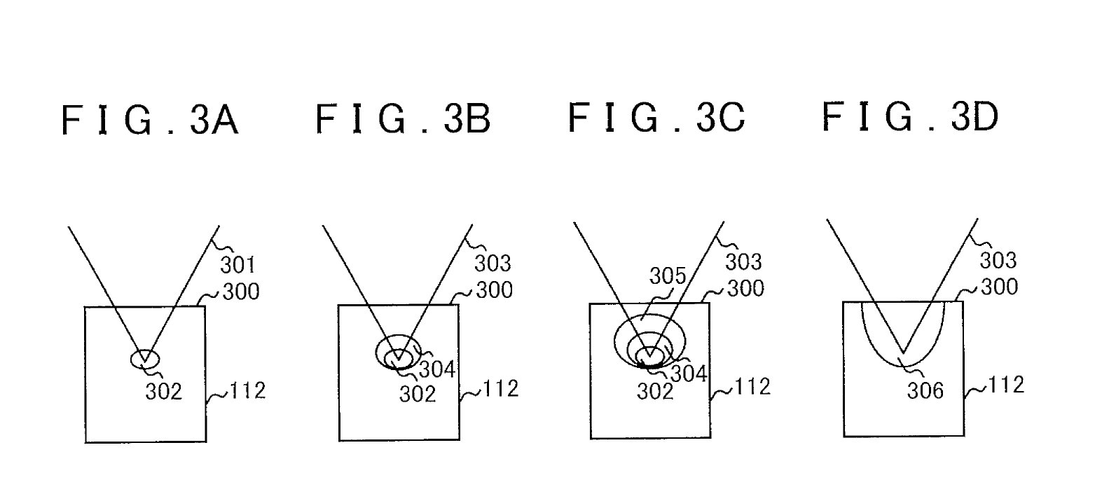

A laser annealing method for annealing the processing object from the inside to the surface in accordance with the present embodiment will be explained below with reference to FIGS. 3A to 3D. FIGS. 3A to 3D are schematic diagrams for explaining the laser annealing according to the present embodiment. In the present embodiment, the processing object 112 is a semiconductor material.

First, the processing object 112 is placed on the XYZ stage 111, and the focus position in which light is converged by the lens 110 is set. Then, a laser beam is generated from the light source 102 and, as shown in FIG. 3A, a light absorptance increase region 302 is formed by converging a femtosecond laser beam 301 at a predetermined position inside the processing object 112.

More specifically, where the user inputs the depth at which the light absorptance increase region 302 should be formed (the distance from a surface 300 of the processing object 112 inward) and the refractive index of the processing object 112 from the input operation unit 115, the control unit 114 moves the XYZ stage 111 and controls the XYZ stage 111 on the basis of the reference position stored in the RAM and the user's input such that the focus point created by the lens 110 is at the predetermined position inside the processing object 112. At the same time, the control unit 114 controls the shutters 208, 212 so as to open both shutters 208, 212. Therefore, a femtosecond laser beam and a nanosecond laser beam are emitted from the light source 102.

Then, the control unit 114 controls the output attenuator (not shown in the figure), which is provided between the light source 102 and the dichroic filter 109, such that the output of the femtosecond laser beam generated from the short-pulse light source 102a is attenuated to the energy that allows multi-photon absorption to occur but does not allow the laser focus point and the periphery thereof to be melted by heat. The control unit 114 then moves the XYZ stage 111 so that the laser beam is scanned at a predetermined scanning rate along an annealing plan line. As a result, the light absorptance increase region 302 is formed along the annealing plan line at a predetermined depth from the surface 300. In this case, the femtosecond laser beam 301 is not required to have the energy (energy density) such as to anneal the processing object 112, and may have energy such as to induce plasma in a solid body or a photoionization effect. Thus, the power of the femtosecond laser beam 301 as the first pulse laser beam may be sufficient for generating plasma in the processing object 112 and is not required to be such as to generate a large amount of heat and anneal the processing object 112. Further, the femtosecond laser beam 301 is caused to be incident under the conditions causing no ablation of the processing object 112. For example, where the processing object 112 is silicon, the threshold of energy causing ablation is 0.1 J/cm² to 0.2 J/cm². Therefore, the femtosecond laser beam 301 with energy equal to or less than 0.1 J/cm² may be caused to be incident on the silicon surface. In this case, the light absorptance of the transparent material temporarily rises due to auto-absorption (avalanche absorption) of plasma in the solid body or photoionization. Since the internal plasma and photoionization occur only in a region with a high photon density, the objective is to form locally a portion with a high light absorptance in the transparent material.

The light absorptance increase region 302 is irradiated with the nanosecond laser beam 303 before the light absorptance of the light absorptance increase region 302 returns to the original value. In the present embodiment, since the delay circuit 106 is provided, as shown in FIG. 1, when the femtosecond laser beam 301 and the nanosecond laser beam 303 are generated at the same time from the light source 102, the nanosecond laser beam 303 is incident upon the light absorptance increase region with a delay by a certain time with respect to the femtosecond laser beam 301. It is preferred that the nanosecond laser beam 303 spatially and/or temporally overlap the femtosecond laser beam 301. Where the irradiation is performed with the nanosecond laser beam 303 (the laser beam that is transparent with respect to the processing object 112), which is the second pulse laser beam, the nanosecond laser beam 303 is absorbed by the light absorptance increase region 302, which has been formed temporarily, without absorption by the surface 300 of the processing object 112, and the inside of the processing object 112 can be locally heated. With such heating, a high-temperature portion 304 including the light absorptance increase region 302 is formed.

In semiconductor materials, the absorptance of light typically increases at a high temperature. In the present embodiment, plasma is generated inside the processing object 112 by the femtosecond laser beam 301 as the first pulse laser beam, the light absorptance increase region (high-temperature portion) 302 is formed, the nanosecond laser beam 303 as the second pulse laser beam is absorbed by the light absorptance increase region 302, and the light absorptance increase region 302 is converted into the high-temperature portion 304. In this case, where the high-temperature portion 302 is further irradiated with the nanosecond laser beam 303, the nanosecond laser beam 303 is absorbed by the high-temperature portion 302 and, therefore, can be easily absorbed on the laser beam incidence side (surface 300 side) due to the thermal diffusion effect or the like. As a result, the temperature of the region 304 of the high-temperature portion 302 on the laser beam incidence side thereof increases and this region becomes the high-temperature portion 304 (FIG. 3B). Further, the temperature of a region 305 on the laser beam incidence side with respect to the high-temperature portion 304 rises due to the thermal diffusion from the high-temperature portions 302, 304. The light absorptance of the region 305 and the amount of nanosecond laser beam 303 absorbed in region 305 also increases with the increase in the temperature of the region 305. Therefore, the region 305 becomes a high-temperature portion (FIG. 3C). Where such operations are repeated, the high-temperature portion formed by the irradiation with the nanosecond laser beam expands from the light absorptance increase region 302 toward the surface 300 side and reaches the surface 300, and an annealed region 306 can be formed (FIG. 3D). Thus, through irradiation with the nanosecond laser beam 303, the annealing is performed from the light absorptance increase region 302 as a starting point to the surface 300.

In the present embodiment, by adjusting the repetition frequency of the first and second pulse laser beams and the processing rate (scanning rate), it is possible to adjust the annealing depth (distance from the substrate surface in the depth direction).

As mentioned hereinabove, in the present embodiment, the irradiation with the femtosecond laser beam 301 as the first pulse laser beam serves to form the light absorptance increase region 302 inside the processing object 112 and functions to create a trigger for inducing good annealing in a deep portion of the processing object 112 even with the nanosecond laser beam 303. Meanwhile, the irradiation with the nanosecond laser beam 303 as the second pulse laser beam functions to implement heating necessary for the annealing in the zone from light absorptance increase region 302 to the surface 300.

Thus, in the present embodiment, the heating contributing to annealing is performed by the nanosecond laser beam 303, but the region where the absorptance of the nanosecond laser beam is temporarily increased (light absorptance increase region 302) is formed inside the processing object 112. Further, the light absorptance increase region 302 serves as a starting point for the heating with the nanosecond laser beam 303. Where the annealing is performed from the surface 300 to a deep region, the nanosecond laser beam 303 absorbed by the processing object 112 may not reach the region to be annealed under the sufficient condition for the annealing. Even when such a nanosecond laser beam 303 is used, however, the method of the present embodiment can cause the absorption of the nanosecond laser beam sufficient for annealing in the region to be annealed. This is because the light absorptance increase region 302 has been formed in advance in the region that should be annealed, and the nanosecond laser beam 303 can be caused to be absorbed in the light absorptance increase region 302 at a ratio higher than that in other regions. Therefore, laser annealing can be performed to the deep region of the processing object 112.

In the present embodiment, the direction in which the laser annealing advances (the direction in which the high-temperature portion expands) is also taken into account in order to perform laser annealing to the deep region of the processing object 112. In the present embodiment, the annealing from the inside of the processing object 112 toward the outside is induced in a state in which the predetermined region (corresponds to the light absorptance increase region) inside the processing object 112 is annealed and the region on the surface 300 side is not annealed. At the initial stage of laser annealing, only the light absorptance increase region 302 formed inside the processing object 112 and the vicinity thereof are crystallized by laser annealing. Therefore, the region on the surface 300 side therefrom has not yet been crystallized and has a low light absorptance. As a result, the nanosecond laser beam 303 can be transferred in a specific amount sufficient for the formation of new high-temperature portions to the high-temperature portions 304, 305 formed by irradiation with the nanosecond laser beam 303. Thus, it is preferred that laser annealing be performed from the inside of the processing object 112 to the outside (surface 300 side). In the present embodiment, the light absorptance increase region 302 is formed by the femtosecond laser beam 301, and laser annealing is performed by the nanosecond laser beam 303 when the light absorptance increase region 302 is maintained. Therefore, the light absorptance increase region 302 can be locally formed in a state with a low surrounding absorptance inside the processing object 112, and laser annealing directed from the inside of the processing object 112 toward the outside can be performed.

In the present embodiment, the width of the annealed region 306 is larger than that of the laser beam irradiation region. In particular, in JP 2006-148086 A and JP 2006-173587 A, the annealing performed by multi-photon absorption is presumed. Since practically no thermal diffusion occurs with the femtosecond laser beam used for multi-photon absorption, the annealing width in one-cycle laser scanning decreases. By contrast, in the present embodiment, since heating relating to the actual laser annealing is performed by the nanosecond laser beam, thermal diffusion can be increased over that in the case of the femtosecond laser beam. Therefore, the width of the annealed region 306 can be increased and the annealed region created by one scan of the laser beam can be increased. As a result, the number of scans can be reduced and the processing time can be shortened.

Further, in the present embodiment, since the heating relating to laser annealing is performed by the nanosecond laser beam rather than the femtosecond laser beam, even when dirt or defects are present on the surface of the processing object 112, no ablation is caused thereby. Therefore, the occurrence of ablation due to unforeseen factors during laser annealing can be prevented and damage of the substrate surface by the laser beam used for laser annealing can be reduced.

In JP 2006-148086 A and JP 2006-173587 A, actual laser annealing is performed by multi-photon absorption. In the multi-photon absorption, the absorptance changes nonlinearly with variations in input energy, and very small changes in the input energy cause significant difference in the amount of generated heat. By contrast, in the present embodiment, the heating relating to actual laser annealing is performed by the nanosecond laser beam that is linearly absorbed by the processing object 112. As a result, the amount of generated heat is proportional to the laser beam power and the amount of heat can be easily controlled.

### EXAMPLES

A phosphorus-doped Si substrate was used as the processing object 112, and the Si substrate was laser annealed according to the present embodiment.

In the first and second examples, a femtosecond laser beam with a wavelength of 1050 nm, a repetition frequency of 1 MHz, and a pulse width of 800 fs was used as the first pulse laser beam, and a nanosecond laser beam with a wavelength of 1050 nm, a repetition frequency of 1 MHz, and a pulse width of 10 ns was used as the second pulse laser beam. The power of the femtosecond laser beam and nanosecond laser beam was set to the values shown in Table 1. The femtosecond laser beam and nanosecond laser beam had a spot diameter of 130 μm, and the scanning rate of the XYZ stage 111 was 600 mm/s. The time interval between the femtosecond laser beam and nanosecond laser beam was 3 ns. In the present examples, the region of the Si substrate, which was the processing object 112, at a depth of about 1 μm was doped with phosphorus. Accordingly, in the present examples, the laser annealing of the Si substrate was performed to a depth of 1 μm.

TABLE 1

| | Power (W) | |
|---|---|---|
| | Femtosecond | |
| | laser beam | Nanosecond laser beam |
| First Example | 2.8 | 14.1 |
| Second Example | 4.7 | 10.3 |
| First Comparative Example | 0 | 14.1 |
| Second Comparative Example | 0 | 10.3 |

In the first and second comparative examples, the annealing was performed as in the first and second examples, but without using the femtosecond laser beam. Thus, in the first and second comparative examples, a nanosecond laser beam with a wavelength of 1050 nm, a repetition frequency of 1 MHz, and a pulse width of 10 ns was used. The power of the nanosecond laser beam in the first and second comparative examples is shown in Table 1. The nanosecond laser beam in the first and second comparative examples had a spot diameter of 130 μm, and the scanning rate of the XYZ stage 111 was 600 mm/s. Further, in the first and second comparative examples, the region of the Si substrate, which was the processing object, at a depth of about 1 μm was doped with phosphorus.

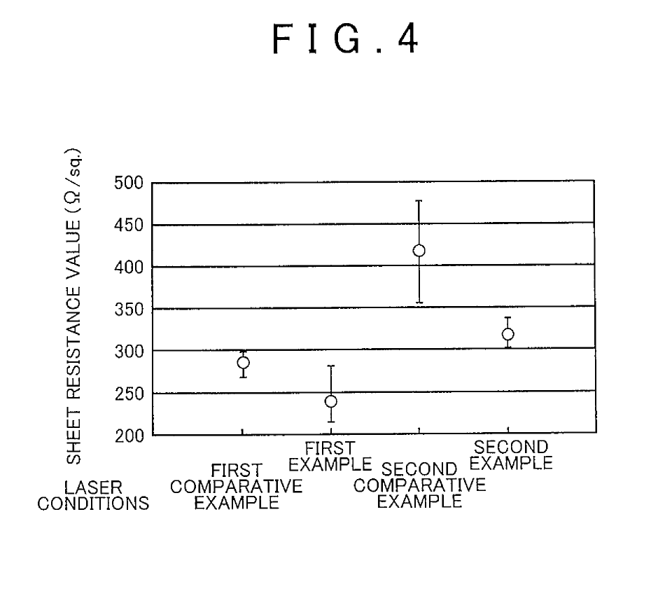

FIG. 4 shows the sheet resistance value obtained in the first and second examples and first and second comparative examples. As shown in FIG. 4, in the first and second comparative examples, the wavelength of the nanosecond laser beam was 1050 nm, and certain annealing was caused even by single-photon absorption. However, by forming the light absorptance increase region by irradiation with the femtosecond laser beam prior to irradiation with the nanosecond laser beam, as in the first and second examples, the sheet resistance value can be reduced (annealing effect can be increased) by comparison with that in the first and second comparative examples, in which the irradiation with the femtosecond laser beam has not been performed, under the same conditions. This is supposedly because, as a result of using femtosecond laser beam irradiation prior to the nanosecond laser beam irradiation, plasma was generated inside the Si substrate and the absorption of the nanosecond laser beam was facilitated, thereby causing annealing and activating the doped ions.

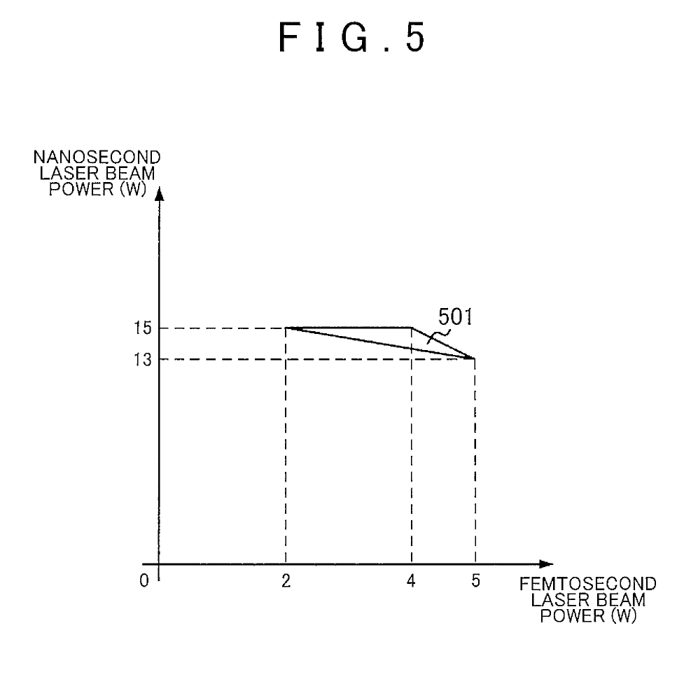

In the present examples, characteristics other than the power of the nanosecond laser beam and the power of the femtosecond laser beam were fixed, and the power of the nanosecond laser beam and the power of the femtosecond laser beam were changed. FIG. 5 shows the relationship between the power of the nanosecond laser beam and the power of the femtosecond laser beam at which the annealing can be realized in the present examples.

Referring to FIG. 5, effective annealing can be performed, provided that the conditions are within a region 501. Where the power of at least one of the femtosecond laser beam and the nanosecond laser beam is below that in the region 501, the resistance value increases as the power decreases. Therefore, the power of the nanosecond laser beam and the power of the femtosecond laser beam may be determined according to the acceptable level of the user. Meanwhile, where the power of the femtosecond laser beam is higher than 5 W, ablation is caused by the femtosecond laser. Where the power of the nanosecond laser beam is larger than 15 W, the substrate surface is damaged by the nanosecond laser beam. Therefore, in the present examples, it is preferred that the power of the femtosecond laser beam be equal to or less than 5 W and the power of the nanosecond laser beam be equal to or less than 15 W to reduce the damage due to the laser beam irradiation.

### Second Embodiment

In the present embodiment, the beam spot diameter and laser beam focus point position of the first pulse laser beam (for example, femtosecond laser beam) and the second pulse laser beam (for example, nanosecond laser beam) are preferably set such that: (1) the conditions (energy density, pulse width, etc.) at which the first pulse laser beam generates multi-photon absorption and induces plasma (light absorptance increase region) are fulfilled, and (2) the second pulse laser beam is absorbed by the plasma (light absorptance increase region) generated by the first pulse laser beam.

Considered below is the case in which a femtosecond laser beam is used as the first pulse laser beam and a nanosecond laser beam is used as the second pulse laser beam. Plasma generated by the femtosecond laser beam is generated close to the focus point. The plasma is not generated where the energy density is not equal to or higher than a predetermined value. Therefore, the plasma size is apparently slightly less than the beam diameter of the femtosecond laser beam. Since the nanosecond laser beam is absorbed by the plasma (light absorptance increase region), it is desirable that the spot diameter of the nanosecond laser beam be about the size of the spot diameter of the femtosecond laser beam. Such a setting can reduce energy wasted in the femtosecond laser beam and nanosecond laser beam.

What is claimed is:

1. A laser processing apparatus comprising:
a laser beam generating device that generates a first pulse laser beam for temporarily increasing a light absorptance in a predetermined region of a processing object, and a second pulse laser beam to be absorbed in the predetermined region in which the light absorptance has temporarily increased; and
a support portion that is provided on a downstream of the first pulse laser beam and the second laser beam generated by the laser beam generating device and has a placement surface for placing the processing object, wherein
the laser beam generating device emits the second pulse laser beam with a delay with respect to the first pulse laser beam by a delay time within a predetermined period of time before the light absorptance that has temporarily increased in the predetermined region returns to an original value.

2. The laser processing apparatus according to claim 1, wherein the laser processing apparatus performs laser annealing by heating a region including the predetermined region by irradiating, with the second pulse laser beam, the predetermined region in which the light absorptance has temporarily increased.

3. The laser processing apparatus according to claim 1, wherein a pulse width of the second pulse laser beam is longer than a time in which thermal conduction occurs from the predetermined region in which the light absorptance has temporarily increased.

4. The laser processing apparatus according to claim 1, wherein irradiation with the first pulse laser beam is performed under a condition such that the processing object is not ablated.

5. The laser processing apparatus according to claim 1, wherein the first pulse laser beam is a femtosecond laser beam, and the second pulse laser beam is a nanosecond laser beam.

6. The laser processing apparatus according to claim 1, wherein a spot diameter of the first pulse laser beam is substantially equal to a spot diameter of the second pulse laser beam.

7. A laser processing method comprising:
irradiating a predetermined region of a processing object with a first pulse laser beam for temporarily increasing a light absorptance of the predetermined region; and
irradiating the processing object with a second pulse laser beam to be absorbed by the predetermined region such that the predetermined region in which the light absorptance has temporarily increased and an irradiation region of the second pulse laser beam at least partially overlap, before the light absorptance in the region in which the light absorptance has temporarily increased returns to an original value.

8. The laser processing method according to claim 7, wherein heating treatment is performed on a region including the predetermined region through absorption of the second pulse laser beam by the predetermined region.

9. The laser processing method according to claim 8, wherein the heating treatment is laser annealing.

10. The laser processing method according to claim 7, wherein a pulse width of the second pulse laser beam is longer than a time in which thermal conduction occurs from the predetermined region in which the light absorptance has temporarily increased.

11. The laser processing method according to claim 7, wherein the irradiation with the first pulse laser beam is performed under a condition such that the processing object is not ablated.

12. The laser processing method according to claim 7, wherein the first pulse laser beam is a femtosecond laser beam, and the second pulse laser beam is a nanosecond laser beam.

13. The laser processing method according to claim 7, wherein a spot diameter of the first pulse laser beam is substantially equal to a spot diameter of the second pulse laser beam.
